(19) United States
(12) Patent Application Publication
(10) Pub. No.: US 2023/0004803 A1
(43) Pub. Date: Jan. 5, 2023

(54) RECONFIGURABLE MEMTRANSISTORS, FABRICATING METHODS AND APPLICATIONS OF SAME

(71) Applicants: NORTHWESTERN UNIVERSITY, Evanston, IL (US); THE BOARD OF TRUSTEES OF THE UNIVERSITY OF ILLINOIS, Urbana, IL (US)

(72) Inventors: Mark C. Hersam, Wilmette, IL (US); Jiangtan Yuan, Evanston, IL (US); Stephanie E. Liu, Evanston, IL (US); Vinod K. Sangwan, Evanston, IL (US); Amit R. Trivedi, Oak Park, IL (US)

(21) Appl. No.: 17/939,057

(22) Filed: Sep. 7, 2022

Related U.S. Application Data
(63) Continuation-in-part of application No. 17/036,428, filed on Sep. 29, 2020.
Application No. 17/036,428 is a continuation-in-part of application No. 16/770,662, filed on Jun. 8, 2020.
(60) Provisional application No. 63/245,997, filed on Sep. 20, 2021.
(60) Provisional application No. 62/908,841, filed on Oct. 1, 2019.
(60) Provisional application No. 62/599,946, filed on Dec. 18, 2017.

(51) Int. Cl. G06N 3/08; H01L 45/00

(52) U.S. Cl. CPC G06N 3/08; H01L 45/1206; H01L 45/142; H01L 45/143; H01L 45/144; H01L 45/14; H01L 45/16

(57) ABSTRACT

This invention relates to memtransistors, fabricating methods and applications of the same. The memtransistor includes a polycrystalline monolayer film of an atomically thin material. The polycrystalline monolayer film is grown directly on a sapphire substrate and transferred onto an SiO₂/Si substrate; and a gate electrode defined on the SiO₂/Si substrate; and source and drain electrodes spatially-apart formed on the polycrystalline monolayer film to define a channel region in the polycrystalline monolayer film therebetween. The gate electrode is capacitively coupled with the channel region.

### CROSS-REFERENCE TO RELATED PATENT APPLICATIONS

This application claims priority to and the benefit of U.S. Provisional Application No. 63/245,997, filed Sep. 20, 2021, which is incorporated herein in its entirety by reference.

This application is also a continuation-in-part application of U.S. application Ser. No. 17/036,428, filed Sep. 29, 2020, which itself claims priority to and the benefit of U.S. Provisional Application Ser. No. 62/908,841, filed Oct. 1, 2019, which are incorporated herein in its entireties by reference.

This application is also a continuation-in-part application of U.S. application Ser. No. 16/770,662, filed Jun. 8, 2020, which is a U.S. national stage application of PCT Application No. PCT/US2018/065929, filed Dec. 17, 2018, which itself claims priority to and the benefit of U.S. Provisional Application No. 62/599,946, filed Dec. 18, 2017, which are incorporated herein in their entireties by reference.

### STATEMENT AS TO RIGHTS UNDER FEDERALLY-SPONSORED RESEARCH

This invention was made with government support under 1720139 and 1542205 awarded by the National Science Foundation, and DE-NA0003525 awarded by the Department of Energy. The government has certain rights in the invention.

### FIELD OF THE INVENTION

The present invention generally relates to material science, particularly to reconfigurable memtransistors for continuous learning in spiking neural networks, fabricating methods, and applications of the same.

### BACKGROUND OF THE INVENTION

The background description provided herein is to present the context of the invention generally. The subject matter discussed in the background of the invention section should not be assumed to be prior art merely due to its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions. Work of the presently named inventors, to the extent it is described in the background of the invention section, as well as aspects of the description that may not otherwise qualify as prior art at the time of filing, are neither expressly nor impliedly admitted as prior art against the invention.

Exponential improvement in solid-state digital electronics over the past several decades has led to an array of modern ubiquitous technologies such as the Internet of Things, edge computing, artificial intelligence (AI), and machine learning (ML) that are impacting nearly all aspects of society. Recent progress in AI/ML has been primarily driven by software improvements exemplified by the DeepMind AlphaGo program that defeated a world champion in the game of Go. However, running AI/ML algorithms on conventional von Neumann hardware platforms results in substantial energy consumption, which is orders of magnitude higher than that of the human brain. AI/ML hardware accelerators based on neuromorphic architectures are being actively pursued using memristors, phase change memory, and synaptic transistors to improve energy efficiency. These devices imitate specific biological responses, such as synaptic plasticity, where the conductance state is modified by a temporal relation between pre-synaptic and post-synaptic neuron spikes. However, synaptic plasticity in biology is more complex than current neuromorphic demonstrations and involves more than two neurons to regulate the strength of synaptic connections. Therefore, to better mimic complex biological synapses, three-terminal neuromorphic devices have emerged to improve energy efficiency, linearity, and reconfigurability.

In parallel with advances in neuromorphic device concepts, two-dimensional (2D) materials have attracted significant attention as a platform for next-generation electronics. The atomic-level thickness of 2D materials imparts weak screening that allows strong electrostatic tunability and reconfigurability of device responses. For example, monolayer polycrystalline MoS₂ memtransistors have achieved gate-tunable memristive switching. The memtransistor is a promising building block for next-generation bio-realistic neuromorphic systems by co-locating memory and transistor functionality. Dual-gated MoS₂ memtransistors also minimize crosstalk and sneak currents in scalable crossbar architectures, thus simplifying integration challenges that have hindered memristive architectures based on bulk materials. Despite the unique attributes of memtransistors, their implementation in neuromorphic architectures has been limited to standard artificial neural networks, suggesting that their full potential for AI/ML has not yet been realized.

Therefore, a heretofore unaddressed need exists in the art to address the aforementioned deficiencies and inadequacies.

### SUMMARY OF THE INVENTION

In one aspect, this invention relates to a memtransistor. The memtransistor comprises a polycrystalline monolayer film of an atomically thin material, wherein the polycrystalline monolayer film is grown directly on a first substrate and transferred onto a second substrate; and a gate electrode defined on the second substrate; and source and drain electrodes spatially-apart formed on the polycrystalline monolayer film to define a channel region in the polycrystalline monolayer film therebetween, wherein the gate electrode is capacitively coupled with the channel region.

In one embodiment, the atomically thin material comprises two-dimensional (2D) semiconductor material.

In one embodiment, the 2D semiconductor material comprises MoS₂, MoSe₂, WS₂, WSe₂, InSe, GaTe, black phosphorus (BP), or related two-dimensional materials.

In one embodiment, the polycrystalline monolayer film of MoS₂ has well-defined grain boundaries, sub-stoichiometric S:Mo ratio, and predominantly monolayer coverage.

In one embodiment, the first substrate is formed of sapphire, quartz, graphene, or hexagonal boron nitride.

In one embodiment, the second substrate is an SiO₂/Si substrate, or an substrate of a high-k dielectric layer including Al₂O₃ or HfO₂.

In one embodiment, the SiO₂/Si substrate comprises a silicon substrate with a silicon dioxide overlayer.

In one embodiment, the gate, source, and drain electrodes comprise a same conductive material or different conductive materials.

In one embodiment, the polycrystalline monolayer film of MoS₂ has well-defined grain boundaries, sub-stoichiometric S:Mo ratio, and predominantly monolayer coverage.

In one embodiment, the memtransistor is reconfigurable with gate tunability that enables continuous learning that allows selective forgetting of inessential tasks, thus freeing up neural resources to learn new tasks.

In one embodiment, by growing the polycrystalline monolayer film grown directly on the sapphire, quartz, graphene, or hexagonal boron nitride substrate, lattice defects in the polycrystalline monolayer film are reduced and the crystallographic registry is improved, thereby enabling accentuation of the vertical field effect from the gate compared to drain bias induced resistive switching, and heightening reconfigurability of a synaptic learning behavior from long-term potentiation (LTP) to long-term depression (LTD).

In one embodiment, the LTP and the LTD are controlled by the gate bias polarity and not the drain pulse polarity, which parallels biological systems' synaptic weight update and neuroplasticity.

In one embodiment, by mimicking the biological systems, LTP/LTD tuning is achieved by biasing the gate without changing the polarity of drain pulses.

In one embodiment, additional learning behaviors are achieved by varying the temporal evolution of gate bias pulses.

In one embodiment, the gate pulses are used to modulate potentiation and depression, resulting in diverse learning curves and simplified spike-timing-dependent plasticity that facilitate unsupervised learning in a simulated spiking neural network (SNN).

In one embodiment, a library of learning curves obtained from temporal evolution of the pulsing amplitude is used to perform unsupervised image recognition in the SNN with functions of continuous learning.

In one embodiment, the unsupervised learning in the SNN is performed using an experimental memtransistor learning behavior modeled in a simplified spike-timing-dependent plasticity (STDP) scheme.

In another aspect, the invention relates to a circuit comprising one or more memtransistors as disclosed above.

In yet another aspect, the invention relates to an electronic device comprising one or more memtransistors as disclosed above.

In a further aspect, the invention relates a system for continuous learning in a spiking neural network, comprising one or more synaptic units, wherein each synaptic unit comprises one or more memtransistors as disclosed above.

In one embodiment, each synaptic unit has learning and/or unlearning behaviors, with the gate-tunable characteristics of the memtransistors.

In one embodiment, switching LTP-LTD learning behavior is achieved by only reversing the polarity of the gate pulses, while further adjustments in the gate amplitude produced diverse learning curves and thus learning behaviors.

In one aspect, the invention relates a method for fabricating a memtransistor, comprising growing a polycrystalline monolayer film of an atomically thin material on a first substrate; transferring the polycrystalline monolayer film to a second substrate; and forming a gate electrode on the second substrate and source and drain electrodes on the grown polycrystalline monolayer film, wherein the source and drain electrodes define a channel region in the polycrystalline monolayer film therebetween, and wherein the gate electrode is capacitively coupled with the channel region.

In one embodiment, the first substrate is formed of sapphire, quartz, graphene, or hexagonal boron nitride.

In one embodiment, the second substrate is an SiO₂/Si substrate, or an substrate of a high-k dielectric layer including Al₂O₃ or HfO₂.

In one embodiment, the polycrystalline monolayer film is grown by chemical vapor deposition (CVD) on the substrates.

In one embodiment, said transferring comprises coating a polymer film on the polycrystalline monolayer film grown on the first substrate; separating the polymer film with the polycrystalline monolayer film from the first substrate; adhering the separated polymer film with the polycrystalline monolayer film to the second substrate; and removing the polymer film.

In one embodiment, the polymer film is formed of polycarbonate (PC).

In one embodiment, said forming is performed by photolithography.

In one embodiment, the atomically thin material comprises 2D semiconductor material.

In one embodiment, the 2D semiconductor material comprises MoS₂, MoSe₂, WS₂, WSe₂, InSe, GaTe, BP, or related two-dimensional materials.

These and other aspects of the present invention will become apparent from the following description of the preferred embodiment taken in conjunction with the following drawings, although variations and modifications therein may be affected without departing from the spirit and scope of the novel concepts of the invention.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1 shows MoS₂ memtransistor device architecture and characteristics according to embodiments of the invention. Panel a: Schematic of a MoS₂ memtransistor on a SiO₂/Si substrate that was fabricated following transfer of CVD MoS₂ from the sapphire growth substrate. Inset: Optical image of memtransistor devices with channel length of 5μm and channel width of 100 μm. MoS₂ films are highlighted by the dotted rectangles. Scale bar: 100 μm. Panel b: Gate-dependent pinched hysteretic loops of the MoS₂ memtransistor. Black arrows indicate the switching directions. Panel c: Atomic force microscopy topography image (left) shows the MoS₂ film as predominantly monolayer. Lateral force microscopy image (right) reveals the grain boundaries of the polycrystalline MoS₂ film with grain size 4 μm². Scale bars: 1 μm. X-ray photoelectron spectra of Mo and S (bottom), resulting in a calculated ratio of S:Mo of about 1.82. Panel d: Gate and drain bias pulse scheme used for long-term potentiation (LTP) and long-term depression (LTD) characterization. For a fixed V_{D} bias polarity, negative V_{G} results in LTP (gray region) and positive V_{G} results in LTD (blue region). V_{D} pulse width is 50 ms, and V_{G} pulse width is 2000 ms. Panel e: Conductance as a function of pulse number for different gate biases. All drain pulses are 80 V. Panel f: The amplitude of the LTP and LTD curves is modulated as a function of the magnitude of V_{G}.

FIG. 2 shows spiking neural network architecture and simulations according to embodiments of the invention. Panel a: In the preprocessing step, 60,000 digits from the MNIST handwritten digit dataset were used for training. Each digit was composed of 784 grayscale pixels, which were one-to-one mapped to input neurons in the network, defining the input neuron (N=784) layer in the two-layer network. Panel b: The two-layer spiking neural network consisted of the input neuron layer connected to the output neuron layer of M neurons with 784×M synaptic connections. The grayscale intensity of each pixel (e.g., #376-380 from panel a) corresponded to the frequency of applied input pulses (black), where black pixels (e.g., #378) yielded higher frequency pulse trains (i.e., higher neuron firing rate). When the internal state of an output neuron exceeded a threshold, a spiking event was induced, followed by an applied output pulse (blue). Panel c: The time window in which the spiking events of the input and output neurons occur affected the weight update of the respective synaptic connections. If the difference in applied voltage within the defined time window exceeded a positive (negative) voltage threshold, the synaptic connections connected to the spiking input and output neurons experienced potentiation (depression) and a positive (negative) change in synaptic weight. Panel d: STDP learning rules were used to train, classify, and test the two-layer model. The normalized conductance maps from output neuron M1 as a function of digits trained highlight the direct correlation between training and recognition rate. Panel e: Normalized conductance (G) maps for 5 out of 200 output neurons after training with 0, 60, 600, 6,000, and 60,000 digits. These images are weight maps of the inferred digits of the respective output neuron determined by STDP spiking rules. Panel f: Digit recognition rate as a function of training digits for varying numbers of output neurons. Panel g: Recognition rate as a function of the number of output neurons.

FIG. 3 shows tuning the learning behavior of MoS2 memtransistors through gate voltage bias modulation according to embodiments of the invention. Panel a: Gate programming pulse train (equal amplitude) that results in learning curve 1. Panel b: Gate programming pulse train (staircase followed by equal amplitude) that results in learning curve 2. Panel c: A stepwise gate modulation sequence from high to low magnitude (left) results in a relatively larger change in conductance in the initial steps followed by rapid saturation for both LTP and LTD (right). Panel d: A mixture of constant potentiation pulses with stepwise depression pulses (left) results in a gradual and symmetric concave learning behavior (right). Panel e: Inverting the stepwise gate modulation sequence from low to high magnitude (left) results in a concave learning response (right). Source/drain programming pulses are 80 V in all cases.

FIG. 4 shows continuous learning with MoS2 memtransistors according to embodiments of the invention. Panel a: Network architecture for continuous learning consisting of 10 output neurons and H hidden neurons divided into group A and group B with H/2 neurons in each group. Panel b: Since neurons in both groups A and B were trained for Task-1 using the same memtransistor learning curve 1, STDP normalized conductance maps of neurons in both groups show robust learning of the handwritten digits 0 and 1. Panel c: Before mapping Task-2 on weights connected to neurons in group B, those synapses were trained to first unlearn Task-1 by applying memtransistor learning curve 2. Meanwhile, the original learning in group A was essentially unaffected. Panel d: During subsequent training of the network with Task-2, some of the synaptic connections stemming from group A tried to learn digits 3 and 4 but their learning was significantly suppressed due to lateral inhibition from group B neurons, and thus overall knowledge of Task-1 is retained. Panel e: A similar phenomenon occurs in the group B neurons, wherein Task-2 training caused synaptic connections to rigorously learn digits 3 and 4, but retention of Task-1 was further attenuated. Panel f: Recognition accuracies for Task 1, Task 2, and their average as a function of the number of training epochs during the unlearning process of synapses for group B neurons. For fewer Unlearning Epochs, the residual knowledge of Task-1 on group B synapses is significant enough to degrade the Task-2 efficiency due to fewer effective number of neurons. On the other hand, with increasing Unlearning Epochs, the number of neurons contributing to Task-1 and Task-2 each approach H/2, improving the average accuracy.

FIG. 5 shows schematic depiction of the transfer process according to embodiments of the invention. Monolayer MoS₂ film grown on sapphire is first spin-coated with PC (polycarbonate), and then lifted with PC in an aqueous solution. Subsequently, PC/MoS₂ is transferred on a clean SiO₂/Si substrate, followed by PC polymer removal in chloroform solution to obtain the MoS₂ film on SiO₂/Si.

FIG. 6 shows (panel a) characteristic monolayer Raman peaks of MoS₂ with spacing between E_{2g} and A_{1g}≈20 cm⁻¹, and (panel b) PL spectrum of monolayer MoS₂ centered at 1.88 eV.

FIG. 7 shows (panel a) lateral force microscopy image, and (panel b) trace/retrace curves for the grain boundary marked by the dotted line in panel a, according to embodiments of the invention.

FIG. 8 shows sulfur vacancy-induced defect levels that are close to the conduction band of MoS₂ according to embodiments of the invention. At zero gate bias (panel a), the sulfur vacancies are positively charged. When a negative (positive) gate bias is applied as shown in panel b (panel c), the Fermi level of MoS₂ will be lower (higher), leaving the vacancy levels empty (occupied) and the sulfur vacancies will be more (less) positively charged.

FIG. 9 shows cycle-to-cycle variation of a memtransistor device according to embodiments of the invention. The device shows a stable response after 1,000 pulses.

FIG. 10 shows data from a total of 28 devices according to embodiments of the invention. Panel a: Initial conductance has a mean value of 64.1 nS, with maximum and minimum conductance of 65.7 nS and 61.9 nS, respectively. Panel b: After 20 pulses, the conductance has a mean value of 102.9 nS, with maximum and minimum conductance being 134 nS and 76.5 nS, respectively. Panel c: The on/off ratio has a mean value of 160.5%, with maximum and minimum conductance of 204% and 121%, respectively.

FIG. 11 shows conductance maps from other output neurons display all MNIST digits 0-9 for various training digits according to embodiments of the invention.

FIG. 12 demonstrates selective learning-unlearning (i.e., continuous learning) using the two-layer SNN network according to embodiments of the invention. Panel a: Resulting recognition rate as a function of training digits when an interrupted model (represented by panel a of FIG. 3) is injected with new learning parameters from another model (represented by panel b of FIG. 3). Increased training with more digits gradually decreases recognition rate, rather than resetting the device array, highlighting the selective (un)learning capability. Panel b: Conductance maps after training the network under Learning Curve 1 (top row) and 2 (bottom row) from panels a-b of FIG. 3, after the exercise described in panel a.

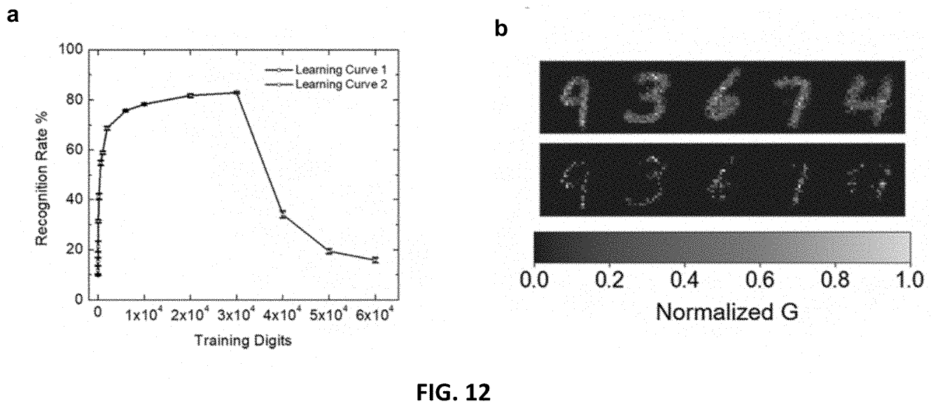

### DETAILED DESCRIPTION OF THE INVENTION

The invention will now be described more fully hereinafter with reference to the accompanying drawings, in which exemplary embodiments of the invention are shown. However, this invention may be embodied in many different forms and should not be construed as limited to the embodiments set forth herein. Rather, these embodiments are provided so that this specification will be thorough and complete and fully convey the invention's scope to those skilled in the art. Like reference numerals refer to like elements throughout.

The terms used in this specification generally have their ordinary meanings in the art, within the context of the invention, and in the specific context where each term is used. Certain terms used to describe the invention are discussed below, or elsewhere in the specification, to provide additional guidance to the practitioner regarding the description. For convenience, certain terms may be highlighted, for example using italics and/or quotation marks. The use of highlighting has no influence on the scope and meaning of a term; the scope and meaning of a term are the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that, as used in the description herein and throughout the claims that follow, the meaning of “a”, “an”, and “the” includes plural reference unless the context clearly dictates otherwise. Also, it will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, or section without departing from the invention's teachings.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures. is turned over, elements described as being on the “lower” side of other elements would then be oriented on “upper” sides of the other elements. The exemplary term “lower”, can, therefore, encompasses both an orientation of “lower” and “upper,” depending on the particular orientation of the figure. Similarly, if the device in one of the figures is turned over, elements described as “below” or “beneath” other elements would then be oriented “above” the other elements. Therefore, the exemplary terms “below” or “beneath” can encompass both an orientation of above and below.

It will be further understood that the terms “comprises” and/or “comprising,” or “includes” and/or “including” or “has” and/or “having”, or “carry” and/or “carrying,” or “contain” and/or “containing,” or “involve” and/or “involving, and the like are to be open-ended, i.e., to mean including but not limited to. When used in this specification, they specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

As used in this specification, “around”, “about”, “approximately” or “substantially” shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated.

As used in this specification, the phrase “at least one of A, B, and C” should be construed to mean a logical (A or B or C), using a non-exclusive logical OR. As used herein, the term “and/or” includes any and all combinations of one or more of the associated listed items.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in a different order (or concurrently) without altering the principles of the invention.

Artificial intelligence and machine learning are growing computing paradigms, but current algorithms incur undesirable energy costs on conventional silicon-based hardware, motivating the exploration of efficient neuromorphic architectures.

One of the objectives of this invention is to provide a novel device concept in the class of three-terminal memtransistors with gate-tunable dynamic learning behavior. Unprecedented synaptic behavior is achieved by fabricating memtransistors from monolayer MoS₂ grown on sapphire by chemical vapor deposition (CVD). Due to reduced lattice defects in CVD MoS₂ grown on sapphire, the vertical field effect from the gate is enhanced compared to drain bias induced resistive switching, heightening the reconfigurability of the synaptic learning behavior from long-term potentiation (LTP) to long-term depression (LTD). Mimicking biological systems, LTP/LTD tuning is achieved by biasing the gate terminal without changing the polarity of drain terminal pulses. Furthermore, additional learning behaviors emerge by varying the temporal evolution of gate bias pulses. The resulting spike-timing-dependent plasticity facilitates unsupervised learning in simulated spiking neural networks (SNN). The gate tunability of these reconfigurable MoS₂ memtransistors uniquely enables continuous learning, which is an underexplored cognitive concept that allows selective forgetting of inessential tasks, thus freeing up neural resources to learn new tasks. Overall, this invention demonstrates that the reconfigurability of memtransistors provides unique opportunities for energy-efficient artificial intelligence and machine learning.

The previous reports that fabricate memristors, memtransistors, or similar resistive switching devices use polycrystalline monolayer MoS₂ film grown directly on SiO₂/Si for ease of fabrication, and do not use transferred MoS₂ initially grown on sapphire wafers. Growing MoS₂ on sapphire imparts crystalline registry to the film and reduced density of lattice defects that are responsible for resistive switching. Thus, in memtransistors fabricated from MoS₂ grown on sapphire, the electric field from the gate has a disproportionally large effect compared to the lateral source-drain field, which incurs qualitative changes in the learning behavior from potentiation to depression. The library of learning curves obtained from temporal evolution of the pulsing amplitude can then be used to perform unsupervised image recognition in a simulated spiking neural network where the concept of continuous learning is demonstrated. An electronic device with potential applications in continuously evolving neural networks has not been demonstrated previously and thus the present reconfigurable MoS₂ memtransistor solves this problem uniquely.

In addition, current commercial solutions for brain-inspired neuromorphic hardware cannot adapt to dynamically varying application needs. For example, a neuromorphic chip intended for automated digit recognition cannot reconfigure itself on-demand to perform both digit recognition and character recognition, which is in stark contrast to real biological systems. Bridging this critical gap between artificial and natural intelligence, we demonstrate synaptic units that can learn and forget by the first demonstration of continuous learning by a solid-state electronic device, namely reconfigurable memtransistor devices using MoS₂ grown on sapphire. Therefore, systems comprised of such synaptic units can assimilate new functionalities by replacing older (unused) functions. Our reconfigurable memtransistors can also dynamically reconfigure themselves to a diverse range of tasks over the device lifetime. This dynamic learning greatly enhances commercial opportunities for artificial intelligence hardware accelerators.

More specifically, the invention relates to memtransistors, fabricating methods, and applications of the same.

In one aspect of the invention, the memtransistor comprises a polycrystalline monolayer film of an atomically thin material, wherein the polycrystalline monolayer film is grown directly on a first substrate and transferred onto a second substrate; and a gate electrode defined on the second substrate; and source and drain electrodes spatially-apart formed on the polycrystalline monolayer film to define a channel region in the polycrystalline monolayer film therebetween, wherein the gate electrode is capacitively coupled with the channel region.

In one embodiment, the atomically thin material comprises two-dimensional (2D) semiconductor material.

In one embodiment, the 2D semiconductor material comprises MoS₂, MoSe₂, WS₂, WSe₂, InSe, GaTe, black phosphorus (BP), or related two-dimensional materials.

In one embodiment, the polycrystalline monolayer film of MoS₂ has well-defined grain boundaries, sub-stoichiometric S:Mo ratio, and predominantly monolayer coverage.

In one embodiment, the first substrate is formed of sapphire, quartz, graphene, or hexagonal boron nitride.

In one embodiment, the second substrate is an SiO₂/Si substrate, or an substrate of a high-k dielectric layer including Al₂O₃ or HfO₂.

In one embodiment, the SiO₂/Si substrate comprises a silicon substrate with a silicon dioxide overlayer.

In one embodiment, the gate, source and drain electrodes comprise a same conductive material or different conductive materials.

In one embodiment, the memtransistor is reconfigurable with gate tunability that enables continuous learning that allows selective forgetting of inessential tasks, thus freeing up neural resources to learn new tasks.

In one embodiment, by growing the polycrystalline monolayer film grown directly on the sapphire, quartz, graphene, or hexagonal boron nitride substrate, lattice defects in the polycrystalline monolayer film are reduced and the crystallographic registry is improved, thereby enabling accentuation of the vertical field effect from the gate compared to drain bias induced resistive switching, and heightening reconfigurability of a synaptic learning behavior from long-term potentiation (LTP) to long-term depression (LTD). It should be noted that other substrates can also be utilized to practice the invention if a similar reduction in defect density can be achieved.

In one embodiment, the LTP and the LTD are controlled by the gate bias polarity and not the drain pulse polarity, which parallels the synaptic weight update and neuroplasticity in biological systems.

In one embodiment, by mimicking the biological systems, LTP/LTD tuning is achieved by biasing the gate without changing the polarity of drain pulses.

In one embodiment, additional learning behaviors are achieved by varying the temporal evolution of gate bias pulses.

In one embodiment, the gate pulses are used to modulate potentiation and depression, resulting in diverse learning curves and simplified spike-timing-dependent plasticity that facilitate unsupervised learning in a simulated spiking neural network (SNN).

In one embodiment, a library of learning curves obtained from temporal evolution of the pulsing amplitude is used to perform unsupervised image recognition in the SNN with functions of continuous learning.

In one embodiment, the unsupervised learning in the SNN is performed using an experimental memtransistor learning behavior modeled in a simplified spike-timing-dependent plasticity (STDP) scheme.

In another aspect, the invention relates a circuitry, comprising one or more memtransistors as disclosed above.

In yet another aspect, the invention relates an electronic device, comprising one or more memtransistors as disclosed above.

In a further aspect, the invention relates a system for continuous learning in a spiking neural network, comprising one or more synaptic units, wherein each synaptic unit comprises one or more memtransistors as disclosed above.

In one embodiment, each synaptic unit has learning and/or unlearning behaviors, with the gate-tunable characteristics of the memtransistors.

In one embodiment, switching LTP-LTD learning behavior is achieved by only reversing the polarity of the gate pulses, while further adjustments in the gate amplitude produced diverse learning curves and thus learning behaviors.

In one aspect, the invention relates a method for fabricating a memtransistor, comprising growing a polycrystalline monolayer film of an atomically thin material on a first substrate; transferring the polycrystalline monolayer film to a second substrate; and forming a gate electrode on the second substrate and source and drain electrodes on the grown polycrystalline monolayer film, wherein the source and drain electrodes define a channel region in the polycrystalline monolayer film therebetween, and wherein the gate electrode is capacitively coupled with the channel region.

In one embodiment, the first substrate is formed of sapphire, quartz, graphene, or hexagonal boron nitride.

In one embodiment, the second substrate is an SiO₂/Si substrate, or an substrate of a high-k dielectric layer including Al₂O₃ or HfO₂.

In one embodiment, the polycrystalline monolayer film is grown by chemical vapor deposition (CVD) on the substrates.

In one embodiment, said transferring comprises coating a polymer film on the polycrystalline monolayer film grown on the first substrate; separating the polymer film with the polycrystalline monolayer film from the first substrate; adhering the separated polymer film with the polycrystalline monolayer film to the second substrate; and removing the polymer film.

In one embodiment, the polymer film is formed of polycarbonate (PC).

In one embodiment, said forming is performed by photolithography.

In one embodiment, the atomically thin material comprises two-dimensional (2D) semiconductor material.

In one embodiment, the 2D semiconductor material comprises MoS₂, MoSe₂, WS₂, WSe₂, InSe, GaTe, black phosphorus (BP), or related two-dimensional materials.

Among other things, the invention has at least the following advantages.
Using polycrystalline, monolayer MoS₂ grown directly on sapphire instead of SiO₂/Si reduces lattice defects, enabling accentuation of the gate field effect in memtransistors.
Attenuated resistive switching from the reduced defect density enables gate-reconfigurable synaptic learning without changing the polarity of drain bias pulses, thus mimicking biological systems more realistically.
These reconfigurable MoS₂ memtransistors allow the gate bias to change the learning behavior from LTP to LTD and vice versa in contrast to existing memristors and memtransistors.
Gate tunability of the learning curves from super-linear to sub-linear LTP and LTD enables unsupervised continuous learning in spiking neural networks where inessential tasks are forgotten selectively to free up resources for learning newer tasks.

The invention may have widespread applications in neuromorphic computing, edge computing, artificial intelligence, machine learning, artificial neural networks, non-volatile memory, sensors, hardware accelerators, and the likes.

These and other aspects of the invention are further described below. Without intent to limit the scope of the invention, exemplary instruments, apparatus, methods, and their related results according to the embodiments of the invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### EXAMPLE

### Reconfigurable MoS₂ Memtransistors for Continuous Learning in Spiking Neural Networks

Artificial intelligence (AI) and machine learning (ML) are growing computing paradigms, but current algorithms incur undesirable energy costs on conventional hardware platforms, thus motivating the exploration of more efficient neuromorphic architectures.

This example discloses a memtransistor with gate-tunable dynamic learning behavior. By fabricating memtransistors from monolayer MoS₂ grown on sapphire, the relative importance of the vertical field effect from the gate is enhanced, thereby heightening reconfigurability of the device response. Inspired by biological systems, gate pulses are used to modulate potentiation and depression, resulting in diverse learning curves and simplified spike-timing-dependent plasticity that facilitate unsupervised learning in simulated spiking neural networks. This capability also enables continuous learning, which is a previously underexplored cognitive concept in neuromorphic computing. Overall, this work demonstrates that the reconfigurability of memtransistors provides unique hardware accelerator opportunities for energy efficient artificial intelligence and machine learning.

Specifically, the range of learning behaviors of memtransistors is expanded through a combination of enhanced electrostatic control and tailored gate bias pulsing profiles. Utilizing monolayer MoS₂ grown on sapphire, memtransistors are efficiently modulated by the gate electrode. Long-term potentiation (LTP) and long-term depression (LTD) are controlled by the gate bias polarity and not the drain pulse polarity, which parallels the synaptic weight update and neuroplasticity in biological systems. This unique capability imparted by 2D materials is leveraged to perform unsupervised learning in a simulated spiking neural network (SNN) using the experimental memtransistor learning behavior modelled in a simplified spike-timing-dependent plasticity (STDP) scheme. The experimental learning curves further enable undemonstrated unsupervised continuous learning in simulated SNNs, which circumvents traditional tradeoffs between image recognition accuracy and resource allocation. This proof-of-concept demonstration is crucial to developing lifelong learning capabilities in artificial intelligence (AI) and machine learning (ML) algorithms in addition to addressing catastrophic forgetting, which is a persistent challenge in neuromorphic computing that requires continuous, energy intensive task updates.

### Materials and Methods

Material growth: Continuous MoS₂ films were synthesized by chemical vapor deposition (CVD) using molybdenum trioxide (Millipore-Sigma, 99.97% trace metals basis) and sulfur powder (Millipore-Sigma, 99.98% trace metals basis). Sapphire (<0001>, MTI Corporation) was used as the substrate for CVD growth. Prior to growth, the substrates were bath-sonicated for 10 min in acetone and 10 min in isopropyl alcohol, followed by deionized water rinsing and nitrogen drying. An oxygen plasma step was applied for 3 min at about 200 mTorr to further clean the substrates. Substrates were then placed in the middle of a 1-inch tube furnace (Lindberg/Blue), with 12 mg molybdenum trioxide and 150 mg sulfur positioned approximately 2 cm and 32 cm away from the substrates upstream. The tube furnace was purged with ultra-high purity Ar (99.99%) at 200 sccm for 10 min and flushed twice (increased pressure to 400 Torr and then pumped down to about 78 mTorr) to create an inert environment. The pressure was kept at 150 Torr at 25 sccm Ar for the remainder of the procedure. To begin the growth, the furnace was first heated to 150° C. in 5 min and held at this temperature for 20 min, then ramped to 800° C. at a rate of 12° C./min and maintained for 20 min, followed by natural cooling. Meanwhile, sulfur power was heated up to 50° C. for 5 min by a heating tape wrapped around the quartz tube and maintained at that temperature for 49 min, then further heating to 150° C. at a rate of 4.5° C./min and held for 23 min, and finally natural cooling to room temperature.

Device fabrication: Synthesized MoS₂ films on sapphire were transferred to silicon substrates with a 285 nm thick silicon dioxide overlayer. Polycarbonate (PC) solution was spin-coated on MoS₂ on sapphire at 1600 rpm for 1 min. After heating the film at 100° C. for 1 min, the sapphire substrate was submerged into a water bath. The PC film with MoS₂ was then separated from sapphire due to the hydrophobic nature of PC film and floated on top of the water bath. A clean oxidized silicon substrate was used to scoop up the floated film. Heating the silicon substrate gradually from 80° C. to 180° C. in 30 minutes allowed the MoS₂ film to adhere fully to the silicon substrate. Finally, the PC film was removed by a chloroform bath for 4 h, followed by isopropyl alcohol rinsing and nitrogen drying preceding device fabrication.

MoS₂ memtransistor devices were fabricated by standard photolithography. In the first step, to pattern metal electrodes, negative photoresist Futurrex NR-9 1000PY was spin-coated at 3,000 rpm for 40 s. The photoresist was baked at 150° C. for 60 s and then exposed for 30 s under a 365 nm wavelength UV light for a dose of 390 mJ/cm². The post-exposure bake was performed at 100° C. for 60 s. Then, the patterns were developed by immersing the substrate in Futurrex resist developer RD 6 for 10 s. Subsequently, Ti/Au (5 nm/50 nm) was evaporated by thermal evaporation and the photoresist was lifted off by MicroChem resist Remover PG. Next, another step of photolithography was performed to define the channel region. Positive resist Microposit S1813 was spin-coated on the substrate at 4,000 rpm for 60 s and then baked at 100° C. for 60 s. After exposing for 15 sat a dose of 35 mJ/cm², the resist was developed in MF-319 for 60 s. Reactive ion etching using an Ar plasma was used to remove the exposed MoS₂ film outside the channel region. Finally, the photoresist was lifted off by Remover PG.

Spiking neuron network simulation: A simulated spiking neural network (SNN) was developed with Python 3.7 and the BRIAN 2.2 simulator package. A simplified spike-timing-dependent plasticity (STDP) learning model was used following previous reports. The MNIST (Modified National Institute of Standards and Technology) dataset of handwritten digits was used to train and test the two-layer neural network, which included one input layer of 784 input neurons and one output layer of M output neurons (M=10, 20, 50, 100, 200). The output neurons were modeled after the leaky-integrate-and-fire model in Equation (1), where t is time, τ=1 (leak time constant), g=γ=1 (multiplicative factor for leaky integrate and fire output neurons), and Iᵢₙₚᵤₜ is the current resulting from resistance modulation of memtransistors connected to the output neurons (summation of the product of weights and internal state variable X for input neurons). The weights of the 784×M synaptic connections were randomly initialized from a Gaussian distribution between 0 and 1, which represented the minimum and maximum normalized conductance.

Linearity and symmetry of the device long-term potentiation and depression curves influenced the SNN weight update rule. This was achieved by fitting the learning curves against the STDP exponential models, as illustrated in Equations (2)-(3) where α and β designate learning rate and linearity fitting parameters, δG normalized conductance change, and subscripts p and m potentiation and depression. Notably, the equations do not specify an explicit time dependence, which may seem contrary to the fundamental basis of STDP. However, the simplified framework adopted here implies the time dependence through the exponential function, since repeated voltage pulses (i.e., large time window between input and output neuron spike events) are likely to evoke smaller changes in conductance than singular voltage pulses (i.e., smaller time window between input and output neuron spike events). The weight update scheme in the simulation also assumed that 784×M synaptic weights were stored on the fabricated devices. Likewise, output neuron dynamics aided in network stability. Lateral inhibition resets the internal state variable (for each output neuron) to zero after an output neuron spiking event to prevent simultaneous spiking among neighboring output neurons. Furthermore, homeostasis corrected each input neuron firing threshold every 200 training digits to aid in network stability. In the corresponding Equation (4), Xₜₕ is the threshold X internal state variable, γ=5 (multiplicative factor to increase threshold modifications for homeostasis), A is the average spiking activity, and T=1/M (target activity to achieve equal firing rates in homeostasis). The simulation used 60,000 training digits and 10,000 testing MNIST digits to measure the recognition rate of the network and was run ten times for reproducibility.

Alternate architectures like multilayer perceptron (MLP) networks were previously implemented to demonstrate the efficacy of memristive hardware and have reported recognition accuracies greater than 90%. While the recognition rates reported by the SNN were lower than those previous MLP reports, we emphasize that recognition rate is not the only figure of merit for neural networks. In this work, we highlight the unique capability of SNNs to conduct unsupervised continuous learning, a significant step in developing lifelong learning capabilities without forgoing energy considerations for neuromorphic computing. Here, key compositional differences between the two networks was briefly distinguished to clarify why SNN was used in this context. MLPs usually have fewer output neurons and layers than SNNs and use backpropagation and continuous activation functions (relying on multiply-and-accumulate summation functions) to propagate strictly spatial information. These methods are relatively straightforward to implement, but are also sensitive to noise and typically more power intensive. Due to these factors, MLPs are more suitable for supervised learning. SNNs in contrast are more structurally complex (with additional layers and input neurons, and thus synaptic connections), and communicate spatiotemporal information via spiking patterns of the input and output neurons, where past spiking history and timing affect such patterns. The bio-realistic STDP algorithm, which informs the frequency and timing of the spiking trains, consequently helps promote Hebbian learning in the connecting synapses. In the SNN, a homeostasis mechanism was also integrated into the structure where the threshold values of the internal states of the output neurons dynamically adjusted based on the activity of the neuron (i.e., the greater post-synaptic neuronal activity would lead to a gradual increase in the threshold X value). This added feature makes the network extremely robust against device-to-device variation and other non-idealities and noise, and thus more desirable for unsupervised learning.

Furthermore, the concept presented in this work of the learning-unlearning capability in memtransistor devices for application to continuous learning can be generalized to other datasets, such as the recently devised dynamic analog to MNIST known as Neuromorphic-MNIST (NMNIST). The use of other datasets can often achieve improved recognition rates. However, we emphasize that recognition rate is not the chief figure of merit that distinguishes STDP-SNN from other neural networks, but rather the unique capability of unsupervised continuous learning that emerges from the integration of 2D memtransistors with SNNs. Additionally, more recent datasets (e.g., NMNIST) have not yet reached a standardized protocol in the literature, which complicates performance benchmarking. Consequently, we limited ourselves to the most established MNIST database in this work.

$$τ \frac{dX}{dt} + gX = γ {I}_{input} \qquad ( 1 )$$

$$δ {G}_{p} = {α}_{p} {e}^{- {β}_{p} \frac{G - {G}_{min}}{{G}_{max} - {G}_{min}}} \qquad ( 2 )$$

$$δ {G}_{m} = {α}_{m} {e}^{- {β}_{m} \frac{{G}_{max} - G}{{G}_{max} - {G}_{min}}} \qquad ( 3 )$$

$$\frac{{dX}_{th}}{dt} = γ ( A - T ) \qquad ( 4 )$$

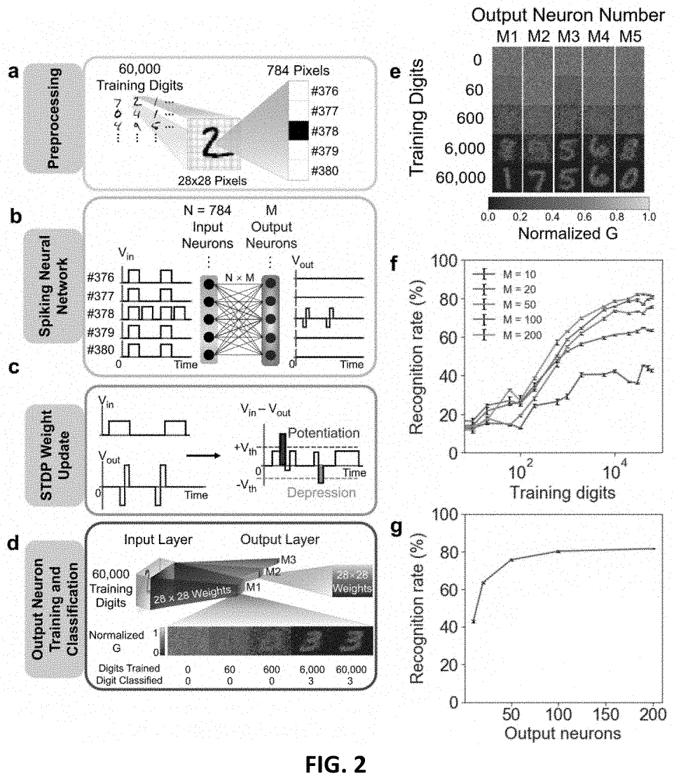

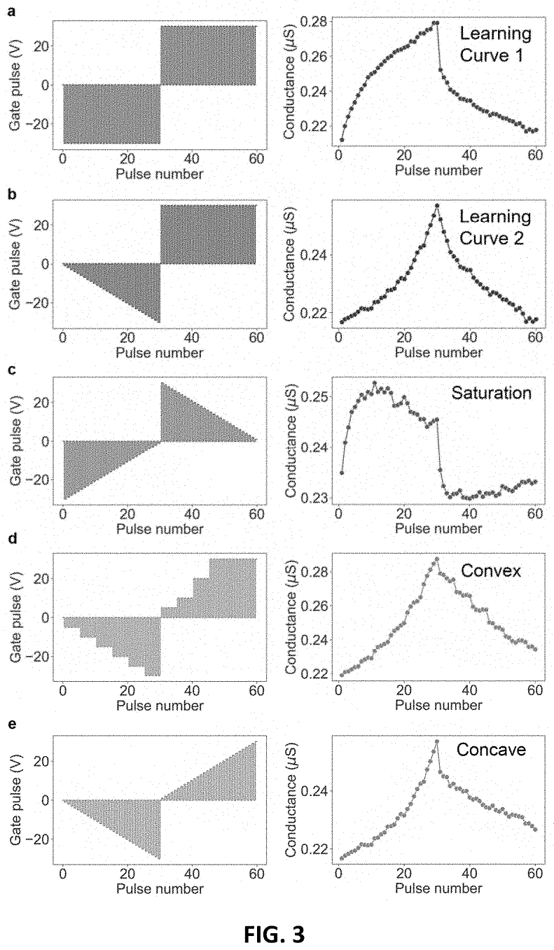

Continuous learning simulation: Similar to the setup above, the simulation framework for SNN-based continuous learning was developed using Python, BRIAN 2.0, and PyTorch packages. A three-layer network including an input-layer with N=784 neurons, a hidden-layer with H=200 neurons, and an output layer with M=10 neurons was used to classify MNIST handwritten digits in a continuous learning setup. While training the network, synaptic weights between the input neurons and hidden neurons were updated using unsupervised STDP learning following Equations (2)-(3). In contrast, the weights between hidden and output neurons were updated using supervised learning to automate the learning-digit association process. Meanwhile, the hidden layer was divided into group A and group B with H/2 neurons each. Such segregation of neurons in groups allowed dynamic programming of neurons in each group for either learning or unlearning. Selective learning/unlearning for neurons in group A and group B was achieved by using corresponding α and β from the learning curves in panels a-b of FIG. 3. Unlearning process is found to correlate with change in the sign change of β for potentiation curves used for learning (negative) and unlearning (positive) (refer to Equations (2)-(3) to observe how varying sign in β impacts degree of unlearning). We considered two-sets of digit recognition tasks (Task-1 and Task-2) to demonstrate suitability of our memtransistors for continuous learning. Task-1 consisted of 11,000 training images of digits 0 and 1, whereas Task-2 had 10,000 training images of digits 3 and 4. The slight discrepancy in the number of training images fed to the network defining Task-1 and Task-2 should have minimal impact on accuracy (refer to panel f of FIG. 2 for network recognition accuracy dependence on number of training digits passed).

Experimental setup: All electrical measurements were carried out in a vacuum probe station (Lakeshore CRX 4K) at a base pressure of 5×10⁻⁵ Torr. The DC voltage sweep, pulse potentiation/depression, and retention measurements were conducted using source meters (Keithley, 2400) and home-built LabVIEW programs.

### Results and Discussion

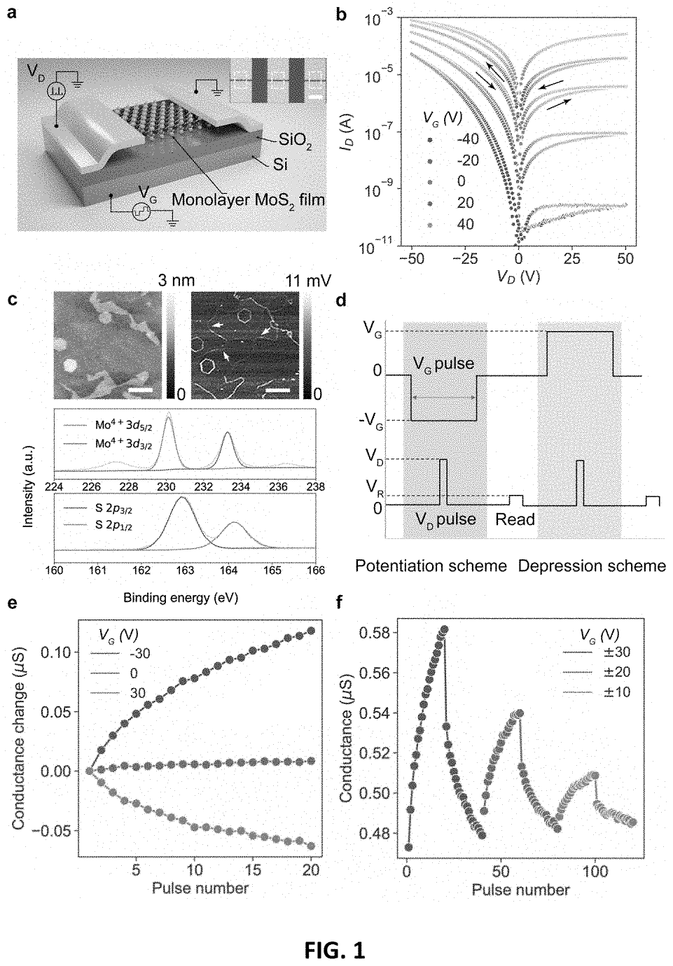

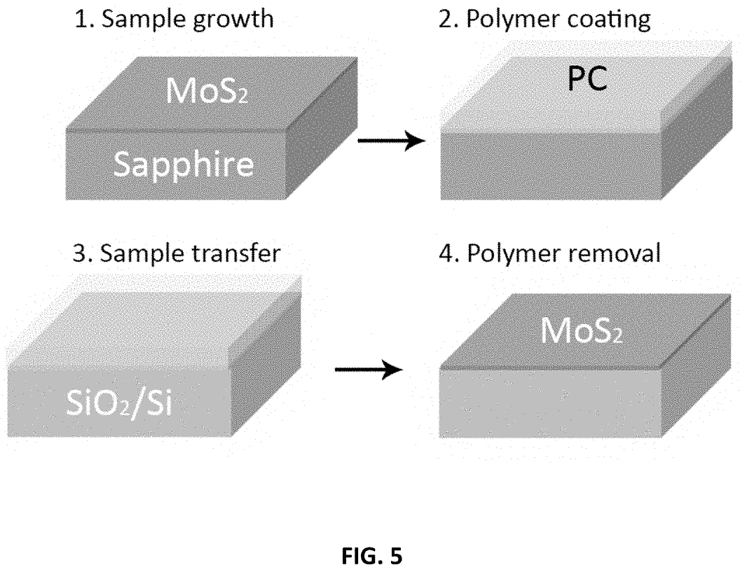

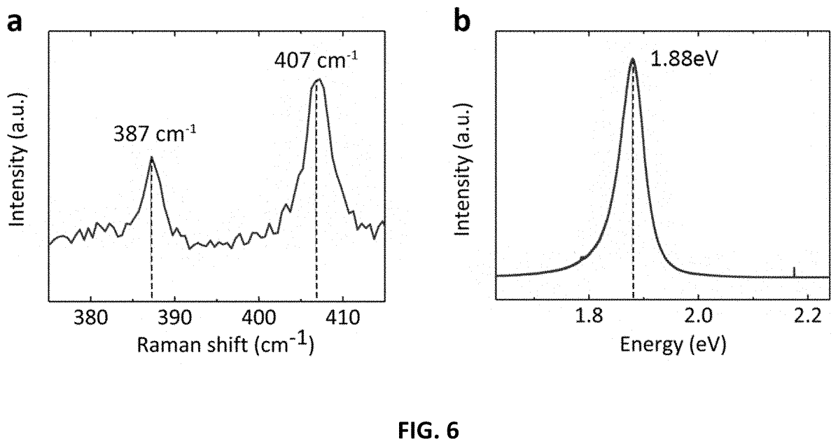

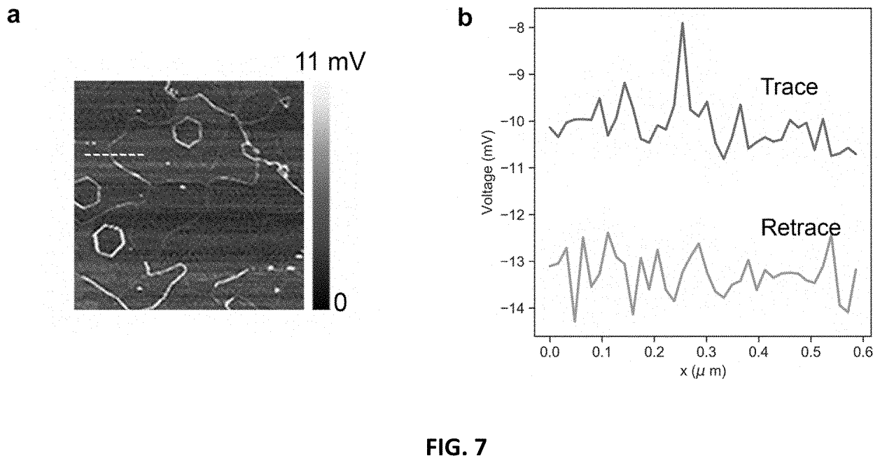

As shown in panel a of FIG. 1 and FIG. 5, polycrystalline MoS₂ films were grown on sapphire substrates by chemical vapor deposition (CVD) and transferred onto SiO₂/Si substrates followed by photolithography to define the devices. The resulting memtransistors showed a strong response to applied gate biases as observed in panel b of FIG. 1. The polycrystalline MoS₂ films were primarily monolayer with small areas of scattered second layer islands. Raman and photoluminescence spectra confirmed the predominantly monolayer nature of the MoS₂ film, with spacing between the A_{1g} and E_{2g} Raman peaks of about 20 cm⁻¹ and a photoluminescence peak at 1.88 eV, in agreement with previous literature, as shown in FIG. 6. Grain boundaries in the polycrystalline film (grain size≈4 μm²) were visualized by comparing lateral force and atomic force microscopy images as illustrated in panel c of FIG. 1 (see FIG. 7 for trace-retrace lateral force curves). Analysis of X-ray photoelectron spectra yielded an S:Mo ratio of about 1.82, which is significantly less than the nominal stoichiometry ratio of 2, suggesting a significant concentration of sulfur vacancies and point defects, as shown in panel c of FIG. 1. This combination of well-defined grain boundaries, sub-stoichiometric S:Mo ratio, and predominantly monolayer coverage was critical in realizing the memtransistor device characteristic.

Program and read pulses were applied to the drain electrode with the source grounded. The resulting memristive response showed a strong gate dependence, where LTP and LTD were achieved by reversing the gate bias's polarity without changing the source-drain pulsing's polarity, as shown in panel e of FIG. 1. To achieve this gate-tunable switching, the memtransistor response from the gate bias was enhanced relative to that from the source-drain bias. In particular, the memristive loop output curve was attenuated to provide a strong response to the gate bias, as shown in panel b of FIG. 1. Thus, CVD growth of polycrystalline MoS₂ on sapphire substrates was critical compared to direct growth on SiO₂/Si substrates. Sapphire substrates have previously been shown to reduce defect density and improve crystallographic registry for CVD-grown MoS₂ films, which reduces the distribution of grain boundary angles. In this manner, at the same source-drain voltage, fewer defects participate in resistive switching, resulting in an attenuation of the memristive response and thus a relative increase in the influence of the gate modulation. The net effect is the ability to qualitatively change the learning behavior as a function of the gate voltage.

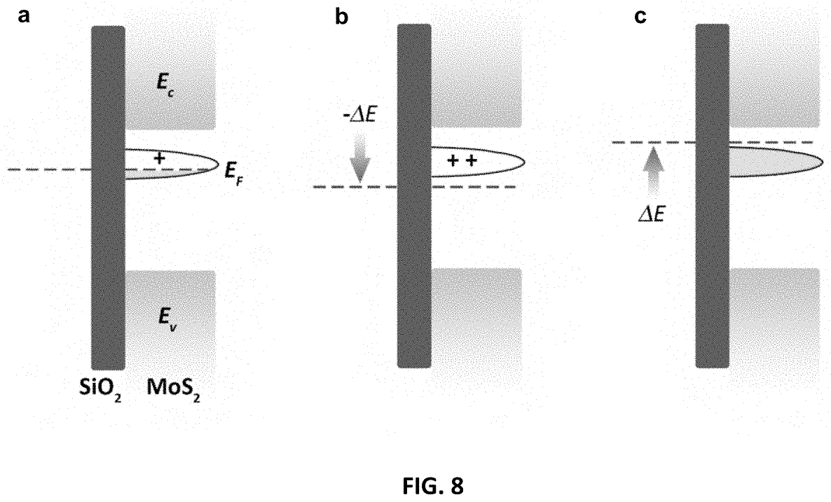

Sulfur vacancies create defect states that can be filled/vacated with a change in the gate bias, as shown in FIG. 8, which further modulates the Schottky barrier at the source/drain electrodes. Previous switching in MoS₂ memtransistors grown on SiO₂ was attributed to tunable Schottky barrier height, resulting from defect migration or charge trapping near the source/drain contacts. Similarly, reduced Schottky barrier height drives the change from LTP to LTD with gate voltage, where a switching direction reversal occurred due to a change in the dominant Schottky diode direction at the drain contact.

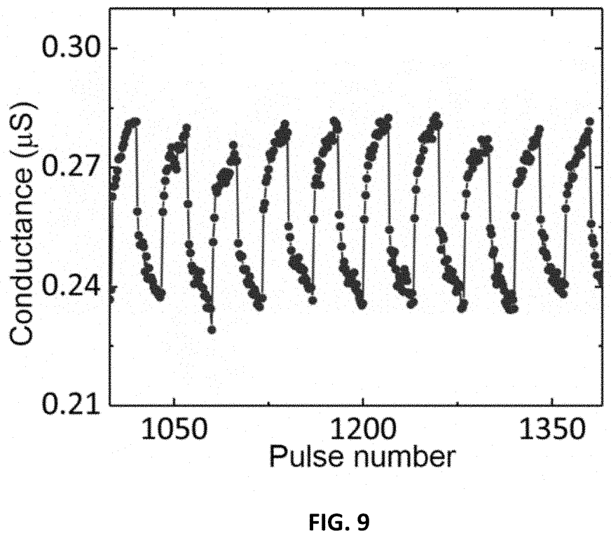

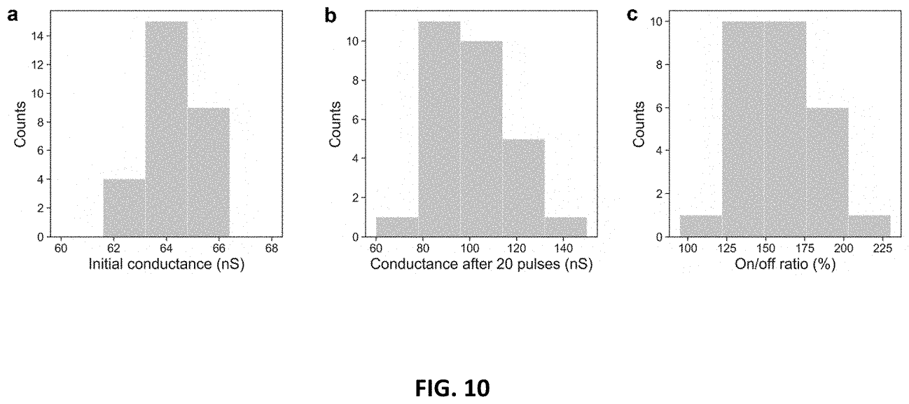

A representative pulsing scheme to achieve gate-tunable LTP and LTD is shown in panel d of FIG. 1. The gate voltage (V_{G}) was held at a predetermined value for each program step while a voltage pulse was applied to the drain electrode (V_{D}). During the subsequent reading step, V_{G} was returned to a zero-bias state while a small V_{D} was applied to read the device's non-volatile conductance (G) state. The combination of a positive V_{D} and a negative V_{G} resulted in LTP behavior, whereas the combination of a positive V_{D} and a positive V_{G} resulted in LTD behavior. The conductance change as a function of pulse number is depicted in panel e of FIG. 1. The conductance modulation for LTP (LTD) was visualized at negative (positive) V_{G}, while the amplitude of the conductance modulation at V_{G}=0 V was ten times smaller than that for V_{G}=30 or −30 V, as shown in panel e of FIG. 1. Furthermore, the amplitude of the conductance modulation increased by a factor of 4.5 as the gate voltage magnitude was increased from 10 V to 30 V, as shown in panel f of FIG. 1. Memtransistor devices showed stable cycle-to-cycle behavior and small device-to-device variation about 20%, as shown in FIGS. 9-10. It is noted that the proof-of-concept devices according to embodiments of the invention used a large lateral geometry and thick (300 nm) dielectric layer, thus requiring relatively high operating voltages. However, it was recently reported that memtransistors can operate at sub-1 volt levels (source-drain terminal) with 20 fJ/bit level switching energy upon optimization of engineering controls during device fabrication. In addition, scaling of device dimensions (less than 500 nm channel length, width), grain size, and dielectric thickness, as well as high-κ dielectric selection, can further reduce gate voltage and overall device footprint. Therefore, memtransistors do not present fundamental issues from a scaling or integration perspective and as such do not necessitate additional peripheral circuits.

To explore the MoS₂ memtransistor device response in neural networks, unsupervised image recognition learning tasks were performed by simulating a two-layer SNN operating on a simplified STDP algorithm. Previous multilayer perceptron demonstrations using backpropagation reported higher recognition accuracies using fewer neurons in supervised learning. However, as accuracy is not a critical figure of merit here, SNN is more appropriate for continuous and unsupervised learning by exploiting the gate-tunable characteristics of memtransistors to achieve bio-realistic STDP (un)learning functions. Panel a of FIG. 2 conceptualizes the workflow setup using the widely accepted MNIST handwritten digits dataset. Experimental learning curves shown in panel f of FIG. 1 were normalized and fitted with an STDP model to yield LTP and LTD parameters, which characterized the curves' learning rate, linearity, and symmetry and directly impacted the STDP weight update.

Panel a of FIG. 2 shows N=784 input neurons connected to =M leaky-integrate-and-fire output neurons (M=10 to 200) to directly map the 28×28 pixel MNIST images. The weights of the 784×M synaptic connections were randomly initialized from a normalized Gaussian distribution and included a built-in 20% noise window to simulate device-to-device variation and other non-idealities. The internal state variable X, analogous to neural membrane potential, was defined for input and output neurons to characterize spiking behavior. The pre-synaptic input neurons were initialized at X=0 and exhibited firing rates proportional to the grayscale intensity of the MNIST images (i.e., darker pixels would more likely induce spiking behavior). As such, a spiking pre-synaptic neuron would propagate its signal to the adjacent synaptic connection for 100 ms, as shown in leftmost panel b of FIG. 2. The X states for post-synaptic output neurons evolved with time following a leaky-integrate-and-fire model and homeostasis mechanism, which dynamically adjusted X values based on output spiking activity. To resemble the winner-take-all biological paradigm, an output neuron spiking event would reset all lateral output neurons to X=0 to inhibit simultaneous output neuron spiking. If the spike occurred (did not occur) within the temporal propagation delay from the input neuron spike, the connecting synapse would potentiate (depress). This relationship between frequency of spiking events and the STDP weight update is visualized with the spiking train pulses in panel c of FIG. 2.

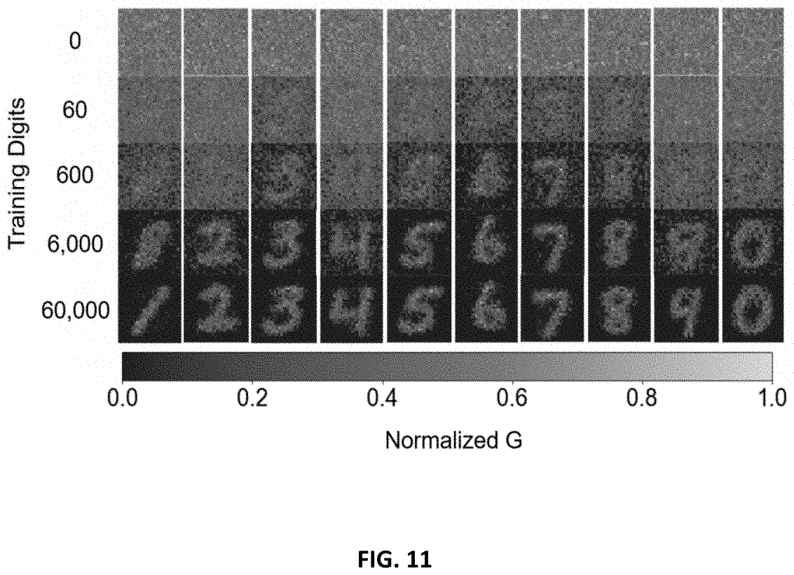

After the network trained for 60,000 training MNIST digits, the output neurons were classified and tested against another set of 10,000 digits, resulting in the calculated recognition rates, as shown in panel d of FIG. 2. Since learning was unsupervised, the classification step was necessary to conduct digit inference. Panels e-g of FIG. 2 illustrate the direct relationship between recognition rate and the number of output neurons and training digits for the ±10 V learning curve from panel f of FIG. 1. The conductance maps highlighted in panel e of FIG. 2 and FIG. 11 depict an arbitrary selection of output neurons during training as more digits are fed through. Each pixel map corresponds to individual synaptic connections mapped to that output neuron, where the color intensity is normalized weight conductance. The small error bars (less than 2%) in panels f-g of FIG. 2 suggest sufficient convergence of the simplified STDP algorithm. Varying the gate modulation voltage from ±10 V to ±30 V did not noticeably affect the final recognition rate, indicating the robustness of the simulated architecture. Higher gate modulation voltage (e.g., ±30 V) would improve current resolution for practical applications, thereby further suppressing device or simulation non-idealities.

Since LTP and LTD responses can be tuned by the magnitude of V_{G}, qualitatively diverse learning curves can also be realized by varying the V_{G} profile during constant V_{D} pulsing (presented as square waves in panel d of FIG. 1). For example, the learning curve shown in panel b of FIG. 3 differs from that of panel a of FIG. 3 in its smooth initial change in concavity, which stems from the gradual increase in V_{G} magnitude (panel b of FIG. 3, left panel) during pulsing compared to a constant V_{G} rate (panel a of FIG. 3, left panel). When a stepwise gate modulation sequence in panel c of FIG. 3 was applied from large V_{G} magnitude to low V_{G} magnitude (left panel), conductance increased significantly at initial steps followed by rapid saturation in both potentiation and depression (right panel). In contrast, a combination of constant and stepwise pulses resulted in a gradual, symmetric convex learning behavior, as shown in panel d of FIG. 3. Concave learning behavior was also achieved through a stepwise increase in V_{G} magnitude, as shown in panel e of FIG. 3. The overall learning curve shape, especially in the potentiation branch, impacts the STDP learning network parameters, thereby influencing simulation behavior as learning or unlearning. The pulsing profile-learning curve shape relation informs design rules to selectively induce (un)learning-conducive behaviors solely based on the gate amplitude or rate of increase thereof. The gate-tunability of the learning curves themselves imply that memtransistor array functionality can be dynamically tuned without changing the underlying hardware, lending versatility and reconfigurability in 2D MoS₂ memtransistors like in biological systems. This capability is especially desirable for applications where varying degrees of adaptability are useful such as online learning where weight updates are concurrent with live input of data.

Dynamic modulation of synaptic weights opens opportunities for SNNs such as continuous learning, an emerging AI/ML framework that enables lifelong adaptation of learning systems in response to dynamic real-world conditions. Conventional AI/ML models learn and exceed human-level performance in certain tasks, although their inherent rigidity can lead to “catastrophic forgetting” of learned information while processing incoming information. Conversely, continuous learning models learn new tasks without forgetting older high-priority tasks, enabling flexibility to perform diverse AI/ML tasks on the same processing resource. Continuous learning models neuro-cognitive mechanisms in the human brain that are responsible for continually acquiring new knowledge by selectively unlearning and overwriting unused, insignificant knowledge. Therefore, under limited implementation resources, continuous learning models are compelling for AI/ML to unlearn lower priority knowledge to accommodate new task learning, which can be realized using tunable LTP and LTD memtransistor learning curves in a modified SNN.

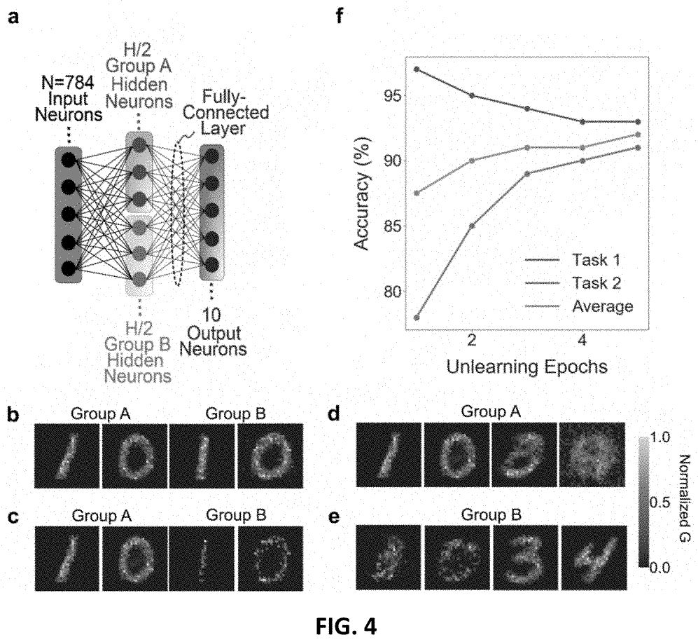

Panel a of FIG. 4 presents the three-layer architecture including N input neurons, H hidden neurons equally divided into groups A and B, and 10 output neurons. Unsupervised continuous learning of the synapses using the STDP learning equations was conducted between the N input and H hidden neurons (conductance maps shown in panels b-e of FIG. 4). After continuous learning, a supervised backpropagation learning scheme between the hidden and output neurons automated the association of learned weights with the MNIST digits (i.e., calculation of accuracy). Similar to the previous setup, homeostasis and lateral inhibition were used for group A and B neurons to simulate competitive learning.

Two recognition tasks were considered: Task-1 was to learn MNIST digits 0 and 1, and Task-2 was to learn MNIST digits 3 and 4. The synaptic platform was initially trained to perform Task-1 such that all H neurons were trained with training images of 0s and 1s using memtransistor learning curve 1, as shown in panel a of FIG. 3. Panel b of FIG. 4 shows conductance maps for group A and B neurons after Task-1 training, revealing efficient learning of the digits 0 and 1. As on-field operations progressed, the network would ideally retain its knowledge of Task-1 and adapt to perform Task-2 under the same resources. Therefore, a subset of hidden neurons must partially forget Task-1 learning to accommodate new knowledge. To enable efficient dynamic task provisioning, group A synapses were allowed to retain knowledge of Task-1, while those for group B were trained to continuously forget Task-1 to free up allocation for Task-2. This outcome was achieved by applying different weight update rules to synapses linked to groups A and B during Task-1 training. Learning curve 1 was applied under the governing STDP equations to reinforce the knowledge stored in group A synapses, while learning curve 2 shown in panel b of FIG. 3 was applied for group B synapses to gradually unlearn Task-1. Notably, this learning and unlearning does not require a change in hardware since the memtransistor learning curve shapes can be tuned with the gate voltage profile.

Conductance maps in panel c of FIG. 4 indicate that group A synapses retained their knowledge of Task-1, while those from group B do not. The total number of neurons associated with Task-1 became effectively less than H, resulting in overall Task-1 recognition degradation. Subsequently, as seen in panels d-e of FIG. 4, the network was trained with 3s and 4s for Task-2 learning using memtransistor learning curve 1 for synapses in both groups A and B. Group B synaptic weights consequently learned the digits 3 and 4 successfully, while some held residual information from Task-1. In parallel, although a few connections from group A attempted to learn digits 3 and 4 during Task-2 training, their learning was substantially suppressed from lateral inhibition from competing group B neurons. Overall, the group A weights remained largely unaffected during network training of Task-2 and maintained robust knowledge of Task-1.

Panel f of FIG. 4 describes the classification accuracy of Task-1 and Task-2 as a function of unlearning training epochs with respect to group B. The lower unlearning epochs limit pinpoints the competitive learning, wherein Group B synapses had higher residue and accuracy of Task-1, revealing that Task-1 effectively operated with more than H/2 neurons, while the learning space for Task-2 was constrained due to only a partial unlearning of the weights responsible for executing Task-1. The upper limit shows the convergence of an effective number of neurons for each task towards H/2. This analysis reveals the benefits of the continuous learning approach, particularly the tradeoff between target accuracy and allocated resource for each task. Consequently, an optimal number of “Unlearning Epochs” can be selected based on task priority. This observation, in addition to the material properties of polycrystalline, sub-stoichiometric, monolayer MoS₂ grown on sapphire that enable reconfigurability by gate-tunable learning, underscores the need for synergistic design of materials, devices, and architectures to achieve bio-realistic functionality in neuromorphic hardware.

In conclusion, the atomically thin and gate-tunable nature of 2D materials were leveraged to fabricate MoS₂ memtransistors with gate-selective control of individual synapses for dynamic reconfigurability of synapses for unsupervised continuous learning. Monolayer MoS₂ on sapphire was critical in enhancing the effect of the gate voltage in the memtransistor device response. Switching LTP-LTD learning behavior was achieved by only reversing the polarity of the gate potential, while further adjustments in the gate amplitude produced diverse learning curves and thus learning behaviors. The resulting learning and unlearning behaviors in a simulated STDP-SNN setup permitted dynamic reallocation of resources for different on-field tasks, thus demonstrating hardware implementation of continuous learning. Further efforts in 2D materials defect engineering, device fabrication optimization, and improved simulation methods are likely to further enhance neuromorphic performance and help realize the full potential of memtransistors as a reconfigurable platform for advanced neuromorphic functionality.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described to explain the principles of the invention and their practical application to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

Some references, which may include patents, patent applications, and various publications, are cited and discussed in the description of this invention. The citation and/or discussion of such references is provided merely to clarify the description of the invention and is not an admission that any such reference is “prior art” to the invention described herein. All references cited and discussed in this specification are incorporated herein by reference in their entireties and to the same extent as if each reference was individually incorporated by reference.

### LIST OF REFERENCES

[1]. Office of Science and Technology Policy. Science & technology highlights in the second year of the trump administration. https://www.whitehouse.gov/wp-content/uploads/2018/03/Science-and-Technology-Highlights-Report-from-the-1st-Year-of-the-Trump-Administration.pdf (accessed Feb. 11, 2020).
[2]. National Science Foundation. Statement on an executive order to maintain American leadership in artificial intelligence. https://www.nsf.gov/news/news_summ.jsp?cntn_id=297658 (accessed Feb. 11, 2020).
[3]. Silver, D.; Schrittwieser, J.; Simonyan, K.; Antonoglou, I.; Huang, A.; Guez, A.; Hubert, T.; Baker, L.; Lai, M.; Bolton, A.; Chen, Y.; Lillicrap, T.; Hui, F.; Sifre, L.; van den Driessche, G.; Graepel, T.; Hassabis, D. Mastering the game of Go without human knowledge. Nature 2017, 550, 354-359.
[4]. Silver, D.; Huang, A.; Maddison, C. J.; Guez, A.; Sifre, L.; van der Driessche, G.; Schrittwieser, J.; Antonoglou, I.; Panneershelvam, V.; Lanctot, M.; Dieleman, S.; Grewe, D.; Nham, J.; Kalchbrenner, N.; Sutskever, I.; Lillicrap, T.; Leach, M.; Kavukcuoglu, K.; Graepel, T.; Hassabis, D. Mastering the game of Go with deep neural networks and tree search. Nature 2016, 529, 484-489.
[5]. J. Mattheij, J. Another way of looking at Lee Sedol vs AlphaGo. https://jacquesmattheij.com/another-way-of-looking-at-lee-sedol-vs-alphago/ (accessed Mar. 17, 2020).
[6]. Xia, Q.; Yang, J. J. Memristive crossbar arrays for brain-inspired computing. Nat. Mater. 2019, 18, 309-323.
[7]. Merolla, P. A.; Arthur, J. V.; Alvarez-Icaza, R.; Cassidy, A. S.; Sawada, J.; Akopyan, F.; Jackson, B. L.; Imam, N.; Guo, C.; Nakamura, Y.; Brezzo, B.; Vo, I.; Esser, S. K.; Appuswamy, R.; Taba, B.; Amir, A.; Flickner, M. D.; Risk, W. P.; Manohar, R.; Modha, D. S. A million spiking-neuron integrated circuit with a scalable communication network and interface. Science 2014, 345, 668-673.
[8]. Yang, J. J.; Pckett, M. D.; Li, X.; Ohlberg, D. A. A.; Stewart, D. R.; Williams, S. Memristive switching mechanism for metal/oxide/metal nanodevices. Nat. Nano. 2008, 13, 429-433.
[9]. Jo, S. H.; Chang, T.; Ebong, I.; Bhadviya, B. B.; Mazumder, P.; Lu, W. Nanoscale memristor device as synapse in neuromorphic systems. Nano Lett. 2010, 10, 1297-1301.
[10]. Zidan, M. A.; Strachan, J. P.; Lu, W. D. The future of electronics based on memristive systems. Nat. Electron. 2018, 1, 22-29.
[11]. van de Burgt, Y.; Lubberman, E.; Fuller, E. J.; Keene, S. T.; Faria, G. C.; Agarwal, S.; Marinella, M. J.; Talin, A. A.; Salleo, A. A non-volatile organic electrochemical device as a low-voltage artificial synapse for neuromorphic computing. Nat. Mater. 2017, 16, 414-418.
[12]. Yeon, H.; Lin, P.; Choi, C.; Tan, S. H.; Park, Y.; Lee, D.; Lee, J.; Xu, F.; Gao, B.; Wu, H.; Qian, H.; Nie, Y.; Kim, S.; Kim, J. Alloying conducting channels for reliable neuromorphic computing. Nat. Nano. 2020, 15, 574-579.
[13]. van der Burgt, Y.; Melianas, A.; Keene, S. T.; Malliaras, G.; Salleo, A. Organic electronics for neuromorphic computing. Nat. Electron. 2018, 1, 386-397.
[14]. Bear, M. F.; Connors, B. W.; Paradiso, M. A. Neuroscience: Exploring the Brain, 2^{nd} ed.; Wolters Kluwer: Philadelphia, 2016.
[15]. Upadhyay, N. K.; Jiang, H.; Wang, Z.; Asapu, S.; Xia, Q.; Yang, J. J. Emerging memory devices for neuromorphic computing. Adv. Mater. Technol. 2019, 4, 1800589.
[16]. Nishitani, Y.; Kaneko, Y.; Ueda, M.; Morie, T.; Fujii, E. Three-terminal ferroelectric synapse device with concurrent learning function for artificial neural networks. J. Appl. 2012, 111, 124108.
[17]. Mennel, L.; Symonowicz, J.; Wachter, S.; Polyushkin, D. K.; Molina-Mendoza, A. J.; Mueller, T. Ultrafast machine vision with 2D material neural network image sensors. Nature 2020, 579, 62-66.
[18]. Novoselov, K. S.; Mishchenko, A.; Carvalho, A.; Castro Neto, A. H. 2D materials and van der Waals heterostructures. Science 2016, 353, aac9439-1-11.
[19]. Sangwan, V. K. and Hersam, M. C. Electronic transport in two-dimensional materials. Annu. Rev. Phys. Chem. 2018, 69, 299.
[20]. Beck, M. E. and Hersam, M. C. Emerging opportunities for electrostatic control in atomically thin devices. ACS Nano 2020 14, 6498-6518.
[21]. Sangwan, V. K.; Lee, H.-S.; Bergeron, H.; Balla, I.; Beck, M. E.; Chen, K.-S.; Hersam, M. C. Multi-terminal memtransistors from polycrystalline monolayer molybdenum disulfide. Nature 2018, 554, 500-504.
[22]. Sangwan, V. K.; Hersam, M. C. Neuromorphic nanoelectronic materials. Nat. Nanotechnol. 2020, 15, 517-528.
[23]. Beck, M. E.; Shylendra, A.; Sangwan, V. K.; Guo, S.; Rojas, W. A. G.; Yoo, H.; Bergeron, H.; Su, K.; Trivedi, A. R.; Hersam, M. C. Spiking neurons from tunable Gaussian heterojunction transistors. Nat. Commun. 2020, 11, 1565.
[24]. Sangwan, V. K.; Jariwala, D.; Kim, I. S.; Chen, K. S.; Marks, T. J.; Lauhon, L. J.; Hersam, M. C. Gate-tunable memristive phenomena mediated by grain boundaries in single layer MoS₂. Nat. Nano. 2015, 10, 403-406.
[25]. Lee, H.-S.; Sangwan, V. K.; Rojas, W. A. G.; Bergeron, H.; Jeong, H. Y.; Yuan, J.; Su, K.; Hersam, M. C. Dual-gated MoS₂ memtransistor crossbar array. Adv. Funct. Mater. 2020, 30, 2003683.
[26]. Lee, C.; Yan, H.; Brus, L. E.; Heinz, T. F.; Hone. J.; Ryu, S. Anomalous lattice vibrations of single- and few-layer MoS₂. ACS Nano 2010, 4, 2695-2700.
[27]. Ling, X.; Lee, Y.-H.; Lin, Y.; Fang, W.; Yu, L.; Dresselhaus, M. S.; Kong, J. Role of the seeding promoter in MoS₂ growth by chemical vapor deposition. Nano Lett. 2014, 14, 464-472.
[28]. Laskar, M. R.; Ma, L.; Kannapan, S.; Park, P. S.; Krishnamoorthy, S.; Nath, D. N.; Lu, W.; Wu, Y.; Raja, S. Large area single crystal (0001) oriented MoS₂. Appl. Phys. Lett. 2013, 102, 252108.
[29]. Esqueda, I. S.; Yan, X.; Rutherglen, C.; Kane, A.; Cain, T.; Marsh, P.; Liu, Q.; Galatsis, K.; Wang, H.; Zhou, C. Aligned carbon nanotube synaptic transistors for large-scale neuromorphic computing. ACS Nano 2018, 12, 7352-7361.
[30]. Querlioz, D.; Bichler, O.; Dollfus, P.; Gamrat, C. Immunity to device variations in a spiking neural network with memristive nanodevices. IEEE Trans. Nanotechnol. 2013, 12, 288-295.
[31]. Feng, X.; Li, S.; Wong, S. L.; Tong, S.; Chen, L.; Zhang, P.; Wang, L.; Fong, X.; Chi, D.; Ang, K.-W. Self-selective multi-terminal memtransistor crossbar array for in-memory computing. ACS Nano 2021, 15, 1764-1774.
[32]. Hu, W.; Lin, Z.; Liu, B.; Tao, C.; Tao, Z.; Zhao, D.; Ma, J.; Yan, R. Overcoming catastrophic forgetting for continual learning via model adaptation. ICLR 2019, 1.
[33]. Parisi, G. I.; Kemker, R.; Part, J. L.; Kanan, C.; Wertmer, S. Continual lifelong learning with neural networks: A review. Neural Netw. 2019, 113, 54-71.
[34]. Aljundi, R.; Babiloni, F.; Elhoseiny, M.; Rohrbach, M.; Tuytelaars, T. Memory aware synapses: learning what (not) to forget. In: Ferrari V., Hebert M., Sminchisescu C., Weiss Y. (eds) Computer Vision—ECCV 2018. ECCV 2018. Lecture Notes in Computer Science, Springer, Cham. 2018; vol 11207; p 144.
[35]. Zhou, W.; Zou, X.; Najmaei, S.; Liu, Z.; Shi, Y.; Kong, J.; Lou, J.; Ajayan, P.; Yakobson, B.; Idrobo, J.-C. Intrinsic Structural Defects in Monolayer Molybdenum Disulfide. Nano Lett. 2013, 13, 2615-2622
[36]. Diehl, P. U.; Cook, M. Unsupervised Learning of Digit Recognition Using Spike-Timing-Dependent Plasticity. Front. Comput. Neurosci. 2015, 9, 99.
[37]. Song, S. H.; Joo, M. K.; Neumann, M.; Kim, H.; Lee, Y. H. Probing Defect Dynamics in Monolayer MoS₂ via Noise Nanospectroscopy. Nat. Commun. 2017, 8, 2121.
[38]. Sanchez Esqueda, I. et al. ACS Nano 12, 7352-7361 (2018)-DOI: 10.1021/acsnano.8b03831.
[39]. R. Stanley Williams, Jianhua Yang, Duncan Stewart, Semiconductor memristor devices, U.S. Pat. No. 8,450,711 B2, May 28, 2013.
[40]. Mark C. Hersam, Vinod K. Sangwan, Deep M. Jariwala, In Soo Kim, Tobin J. Marks, Lincoln J. Lauhon, Gate-tunable atomically-thin memristors and methods for preparing same and applications of same, U.S. Pat. No. 9,515,257 B2, Dec. 6, 2016.
[41]. Minxian Max Zhang, Kathryn Samuels, Jianhua Joshua Yang, R. Stanley Williams, Zhiyong Li, Nonvolatile memory crossbar array, U.S. Publication No. 2017/0271410 A1, Sep. 21, 2017.
[42]. Gregory S. Snider, Neuromorphic circuit, PCT Publication No. WO/2009/113993 A1, Sep. 17, 2009.
[43]. Yi Tang, Venkat Rangan, Jeffrey A. Levin, Subramaniam Venkatraman, Methods and systems for memristor-based neuron circuits, PCT Publication No. WO/2012/006471 A1, Jan. 12, 2012
[44]. Peter A J van der Made, Anil Shamrao Mankar, Spiking neural network, U.S. Publication No. 2020/0143229 A1, May 7, 2020.
[45]. Filip Piekniewski, Eugene Izhikevich, Botond Szatmary, Csaba Petre, Spiking neural network feedback apparatus and methods, U.S. Publication No. 2013/0297541 A1, Nov. 13, 2013.
[46]. Carver A. Mead, Timothy P. Allen, Federico Faggin, Dynamic Synapse for Neural Network, U.S. Pat. No. 4,962,342 A, Oct. 9, 1990.

What is claimed is:

1. A memtransistor, comprising:
a polycrystalline monolayer film of an atomically thin material, wherein the polycrystalline monolayer film is grown directly on a first sapphire substrate (growth on quartz, graphene, or hexagonal boron nitride substrates may also work) and transferred onto a second substrate;
a gate electrode defined on the second substrate; and
source and drain electrodes spatially-apart formed on the polycrystalline monolayer film to define a channel region in the polycrystalline monolayer film therebetween,
wherein the gate electrode is capacitively coupled with the channel region.

2. The memtransistor of claim 1, wherein the atomically thin material comprises two-dimensional (2D) semiconductor material.

3. The memtransistor of claim 2, wherein the 2D semiconductor material comprises MoS₂, MoSe₂, WS₂, WSe₂, InSe, GaTe, black phosphorus (BP), or related two-dimensional materials.

4. The memtransistor of claim 3, wherein the polycrystalline monolayer film of MoS₂ has well-defined grain boundaries, sub-stoichiometric S:Mo ratio, and predominantly monolayer coverage.

5. The memtransistor of claim 1, wherein the first substrate is formed of sapphire, quartz, graphene, or hexagonal boron nitride.

6. The memtransistor of claim 1, wherein the second substrate is an SiO₂/Si substrate, or an substrate of a high-k dielectric layer including Al₂O₃ or HfO₂.

7. The memtransistor of claim 6, wherein the SiO₂/Si substrate comprises a silicon substrate with a silicon dioxide overlayer.

8. The memtransistor of claim 1, wherein the gate, source and drain electrodes comprises a same conductive material or different conductive materials.

9. The memtransistor of claim 1, being reconfigurable with gate tunability that enables continuous learning that allows selective forgetting of inessential tasks, thereby freeing up neural resources to learn new tasks.

10. The memtransistor of claim 1, wherein by growing the polycrystalline monolayer film grown directly on the sapphire substrate, lattice defects in the polycrystalline monolayer film are reduced and crystallographic registry is improved, thereby enabling accentuation of a vertical field effect from the gate compared to drain bias induced resistive switching, and heightening reconfigurability of a synaptic learning behavior from long-term potentiation (LTP) to long-term depression (LTD).

11. The memtransistor of claim 10, wherein the LTP and the LTD are controlled by the gate bias polarity and not the drain pulse polarity, which parallels the synaptic weight update and neuroplasticity in biological systems.

12. The memtransistor of claim 11, wherein by mimicking the biological systems, LTP/LTD tuning is achieved by biasing the gate without changing the polarity of drain pulses.

13. The memtransistor of claim 11, wherein additional learning behaviors are achieved by varying temporal evolution of gate bias pulses.

14. The memtransistor of claim 11, wherein the gate pulses are used to modulate potentiation and depression, resulting in diverse learning curves and simplified spike-timing-dependent plasticity that facilitate unsupervised learning in a simulated spiking neural network (SNN).

15. The memtransistor of claim 14, wherein a library of learning curves obtained from temporal evolution of the pulsing amplitude is used to perform unsupervised image recognition in the SNN with functions of continuous learning.

16. The memtransistor of claim 15, wherein the unsupervised learning in the SNN is performed using an experimental memtransistor learning behavior modelled in a simplified spike-timing-dependent plasticity (STDP) scheme.

17. A circuit, comprising one or more memtransistors according to claim 1.

18. An electronic device, comprising one or more memtransistors according to claim 1.

19. A system for continuous learning in a spiking neural network, comprising:
one or more synaptic units, wherein each synaptic unit comprises one or more memtransistors according to claim 1.

20. The system of claim 19, wherein each synaptic unit has learning and/or unlearning behaviors, with the gate-tunable characteristics of the memtransistors.

21. The system of claim 20, wherein switching LTP-LTD learning behavior is achieved by only reversing the polarity of the gate pulses, while further adjustments in the gate amplitude produced diverse learning curves and thus learning behaviors.

22. A method for fabricating a memtransistor, comprising:
growing a polycrystalline monolayer film of an atomically thin material on a first sapphire substrate;
transferring the polycrystalline monolayer film to a second substrate; and
forming a gate electrode on the second substrate and source and drain electrodes on the grown polycrystalline monolayer film, wherein the source and drain electrodes define a channel region in the polycrystalline monolayer film therebetween, and wherein the gate electrode is capacitively coupled with the channel region.

23. The method of claim 22, wherein the first substrate is formed of sapphire, quartz, graphene, or hexagonal boron nitride.

24. The method of claim 22, wherein the second substrate is an SiO₂/Si substrate, or an substrate of a high-k dielectric layer including Al₂O₃ or HfO₂.

25. The method of claim 22, wherein the polycrystalline monolayer film is grown by chemical vapor deposition (CVD) on the first substrate.

26. The method of claim 22, wherein said transferring comprises:
coating a polymer film on the polycrystalline monolayer film grown on the first substrate;
separating the polymer film with the polycrystalline monolayer film from the first substrate;
adhering the separated polymer film with the polycrystalline monolayer film to the second substrate; and
removing the polymer film.

27. The method of claim 26, wherein the polymer film is formed of polycarbonate (PC).

28. The method of claim 22, wherein said forming is performed by photolithography.

29. The method of claim 22, wherein the atomically thin material comprises two-dimensional (2D) semiconductor material.

30. The method of claim 29, wherein the 2D semiconductor material comprises MoS₂, MoSe₂, WS₂, WSe₂, InSe, GaTe, black phosphorus (BP), or related two-dimensional materials.
